(19) United States
(12) Patent Application Publication
(10) Pub. No.: US 2011/0232727 A1
(43) Pub. Date: Sep. 29, 2011

(54) FLOATING PHOTOVOLTAIC SYSTEM

(76) Inventors: Elvio Cangini, Lugo (Ravenna) (IT); Stelio Poli, Faenza (Ravenna) (IT)

(21) Appl. No.: 13/132,105

(22) PCT Filed: Nov. 27, 2009
(86) PCT No.: PCT/IB2009/007574

§ 371 Date: Jun. 1, 2011

(30) Foreign Application Priority Data
Dec. 2, 2008 (IT) MI2008A002133

(51) Int. Cl. H01L 31/048

(52) U.S. Cl. 136/251

(57) ABSTRACT

A floating photovoltaic system includes a floating structure with a series of floating blocks which form a basically flat floating grid with a float height, a strengthening structure-with a series of strengthening beams movably connected to at least two floating blocks, a supporting structure with one or more supporting frames movably connected to the strengthening beams, one or more photovoltaic panels fixed on the supporting frames, in which the strengthening structure is parallel to the table of the floating structure and is arranged within the float height.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC Not applicable.

### BACKGROUND OF THE INVENTION

1. Field of the Invention

This invention basically concerns a photovoltaic system for transforming solar energy into electrical energy and particularly a floating photovoltaic system to be installed in water and more specifically in internal waters, for example lakes, ponds, mountain lakes, plains, lagoons, etc.

2. Description of Related Art Including Information Disclosed Under 37 CFR 1.97 and 37 CFR 1.98.

Proposals for installing photovoltaic systems in water are well-known, particularly in the sea where the system itself does not take away arable land from agricultural use and has no environmental impact because it is not visible or is only visible in the distance. The known proposals for marine installations of photovoltaic systems envisage both fixed systems anchored on the sea bottom and floating boat-like installations.

The installation of photovoltaic systems on the surface of internal waters, for instance lakes and ponds, requires, on the one hand, the harmonious installation of the photovoltaic system in the existing landscape and, on the other, a structure that adapts to the seasonal variations of the water conditions and to any variations, for instance expansion or reduction of the overall area of the solar panels and modifications to the shape of the installation, required by the plant operator or by the local or regional authorities.

A floating system is disclosed in US 2008/029148 A describing:

A floating structure with a series of floating modular blocks movably connected (by means of structural channels and bolts) to form a basically flat floating grid with a float height,
A strengthening structure with a series of strengthening beams, in which each one of these strengthening beams is movably connected to at least two floating blocks,
A supporting structure including one or more rigid supporting frames movably connected to these strengthening beams,
One or more photovoltaic panels fixed on these supporting frames, in which said strengthening structure is parallel to the floating grid structure level.

A similar system is disclosed in JP 2002 281773 A.

In any case both the above mentioned patents do not provide a holding and limiting structure to keep a carpet of aquatic plants.

The purpose of this invention is, therefore, to provide a floating photovoltaic system which provides the possibility of realizing a carpet of aquatic plants in order to fit harmoniously in the landscape. Another purpose of the present invention is to provide a floating photovoltaic system having characteristics able to facilitate changes in its shape and area and that allow the system to fit harmoniously in the landscape of the installation place.

### BRIEF SUMMARY OF THE INVENTION

These and other purposes shall be achieved by means of a floating photovoltaic system including:

a floating structure with a series of floating modular blocks movably connected to form a basically flat floating grid with a float height,

a strengthening structure with a series of strengthening beams, each one of these strengthening beams is movably connected to at least two floating blocks,

a supporting structure made up of a series of rigid supporting frames movably connected to these rigid beams of the strengthening structure,

a series of photovoltaic panels fixed on these supporting frames, in which said strengthening structure is parallel to the floating grid level and is arranged within the float height.

### BRIEF DESCRIPTION OF THE SEVERAL VIEWS OF THE DRAWINGS

In order to better understand the invention and to appreciate its advantages, there follows a description of some of its embodiments which are not limiting and refer to the attached figures, in which:

FIG. 1 is a top view of a floating photovoltaic system according to one embodiment of the invention,

FIGS. 2 and 3 are perspective views of modular floating blocks of a floating structure of the system according to one embodiment of the invention,

FIG. 4 is a schematised side view of a supporting structure of photovoltaic panels and its connections with a strengthening structure of the system according to one embodiment of the invention,

FIG. 5 is a cross-sectional view according to the V-V line in FIG. 4,

FIG. 6 is a top view of a strengthening beam of the photovoltaic system according to one embodiment,

FIG. 7 is a cross-sectional view according to the VII-VII line in FIG. 6,

FIG. 8 is a top view of a detail of a strengthening beam of the photovoltaic system according to a further embodiment,

FIG. 9 is a cross-sectional view according to the IX-IX line in FIG. 8,

FIG. 10 is an enlargement of the detail X in FIG. 1,

FIG. 11 is a cross-sectional view according to the XI-XI line in FIG. 10,

FIG. 12 is an enlargement of the detail XII in FIG. 1,

FIG. 13 is a side view according to the arrow XIII in FIG. 12,

FIG. 14 is a side view according to the arrow XIV in FIG. 12,

FIG. 15 is an enlargement of the detail XV in FIG. 1,

FIG. 16 is a side view according to the arrow XVI in FIG. 15,

FIG. 17 is an enlargement of the detail XVII in FIG. 1,

FIG. 18 is a side view according to the arrow XVIII in FIG. 17,

FIG. 19 is a cross-sectional view of a flexible joint of a landing stage of the photovoltaic system according to one embodiment,

FIGS. 20 and 21 illustrate the flexible joint of FIG. 19 in two position configurations.

### DETAILED DESCRIPTION OF THE INVENTION

With reference to the figures, a floating photovoltaic system is indicated overall with reference 1.

System 1 comprises a floating structure 2 with a series of floating modular blocks 3 movably connected to form a basically flat floating grid with a float height 4.

System 1 also includes a strengthening structure 5 with a series of strengthening beams 6. Each one of the strengthening beams 6 is movably connected to at least two floating blocks 3 so as to allow the connection of additional structures to the floating structure 2.

In order for photovoltaic panels 7 to be fitted to the floating structure 2, a supporting structure 8 is envisaged with at least one, preferably a series of basically rigid support frames 9, movably connected to the strengthening beams 6. The photovoltaic panels 7 are fixed to the support frames 9 which guarantee support to the panels on basically continuous lines.

In accordance with one embodiment of the invention, the fixing of the photovoltaic panels 7 to the support frames 9 is performed by means of clamps 10 with adjustable opening or height to adapt to photovoltaic panels of different thicknesses.

According to one design of the invention, the strengthening structure 5 is basically parallel to the floating grid table P2 and is arranged within the float height 4. In this way the photovoltaic panels can be supported under or basically aligned with an upper side of the floating structure 2 and thus at a much shorter distance from the water where the system 1 is installed. The result is much less environmental impact and the possibility of harmoniously inserting it in the natural environment.

In accordance with a further aspect of the invention, the floating photovoltaic system 1 includes a structure 11 for holding and limiting a carpet of real or imitation aquatic plants 12. This makes it possible to vary the form and structure of the system 1 visible to a visitor thanks to its “functional” shape dictated by the presence of the photovoltaic panels 7.

The holding and limiting structure 11 may be movably connected to the strengthening structure 5.

According to one embodiment, the holding and limiting structure 11 includes one or more limiting beams 13 arranged at a distance from the floating structure 2 so as to form a limiting line of the system 1 and one or more connecting beams 14 with an external end 15 connected with the limiting beam 13 and an internal end 16 connected to the strengthening structure 5 in a movable manner, whose height can be regulated, so as to be able to adapt the height of the limiting line to the floating line of the photovoltaic system 1.

The connection between the external end 15 of the connecting beam 14 and the limiting beam 13 is preferably a welded or bolted connection.

The adjustable connection between the internal end 16 of connection beam 14 and the strengthening structure 5 preferably includes a vertical eyelet 17 for receiving one or more bolts 18 in a vertical adjustable position (compare FIGS. 13, 16, 18 for example).

The holding and limiting structure 11 also includes an anti-drowning safety net 19 (if a system operator should fall in) and for holding aquatic plants 12. The net 19 is laid in a space between the limiting line defined by the limiting beams 13 and the floating structure 2 and connected to the limiting beams 13 and to the strengthening beams 6.

This net 19 not only provides a safety device which allows to avoid the use of permanent railings in favour of a more harmonious fitting into the landscape, but it also holds aquatic plants like water lilies, within a global shape defined by the limiting beams 13, such as to give the system 1 an acceptable colour, surface structure and shape configuration from an environmental viewpoint.

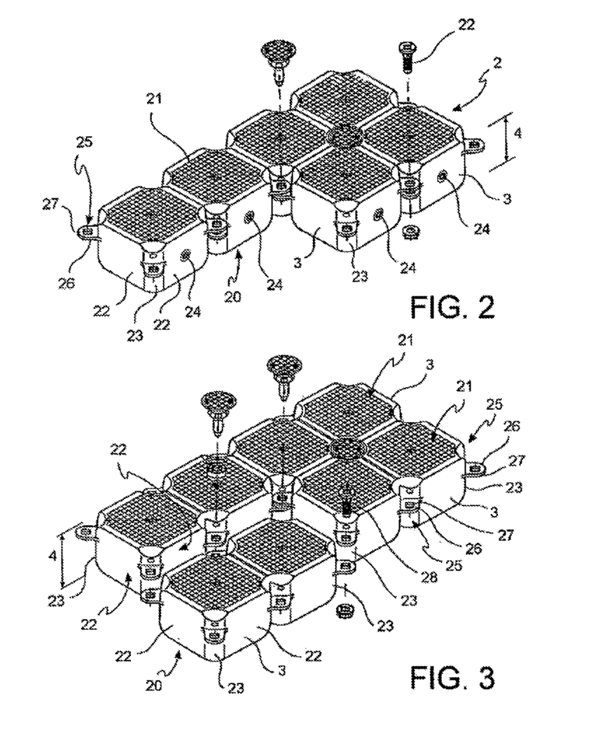

In accordance with one embodiment (FIGS. 2 and 3), the modular floating blocks 3 include hollow bodies of a basically parallelepiped shape with a lower side 20, an upper side 21 and four lateral sides 22 which form four lateral angles 23. In one of the lateral sides 22 a closable opening 24 may be envisaged to allow a partial filling of the internal space of the floating block 3 in order to regulate the upward thrust of the floating block 3 itself. Each floating block 3 includes at least four connection interfaces 25 arranged in proximity of these lateral corners 23 and that include flanges 26 with through openings 27 that can be vertically overlaying and connected by inserting a connecting pin 28.

Advantageously, in all the floating blocks 3, the through openings 27 are arranged in correspondence to a hypothetical intersection line of the two adjacent lateral sides 22. This allows a modular composition at choice of different floating blocks.

The floating blocks 3 are preferably obtained by pressing or blowing synthetic material.

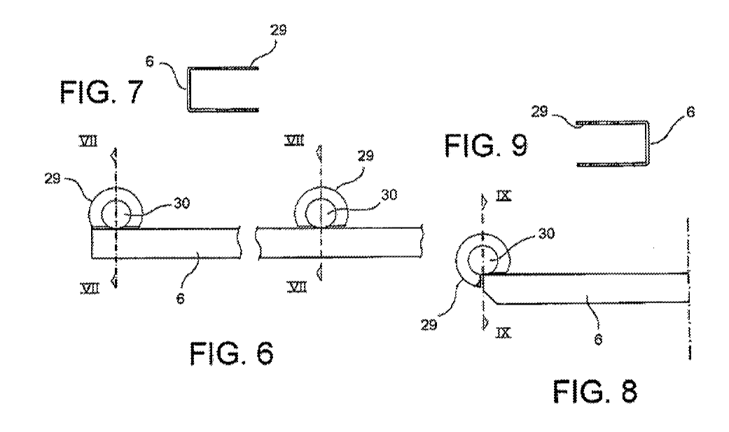

In accordance with one embodiment (FIGS. 6, 7, 8), the strengthening beams 6 include metal profiles, for instance galvanised steel, preferably but not necessarily with an open cross section, for instance u-shaped, with at least two connection fins 29 protruding from this metal profile and that mark openings 30 that can be vertically overlaid on the respective through openings 27 of the connection interfaces 25 of at least two floating blocks 3.

In order to permit the structural connection of the supporting structure 8, of the holding and limiting structure 11 and other auxiliary structures and devices, for instance railings 31, a landing stage 32 and cable-ways (not illustrated in the figures) to the floating structure 2, these strengthening beams 6 can include a series of further portions of dedicated connections.

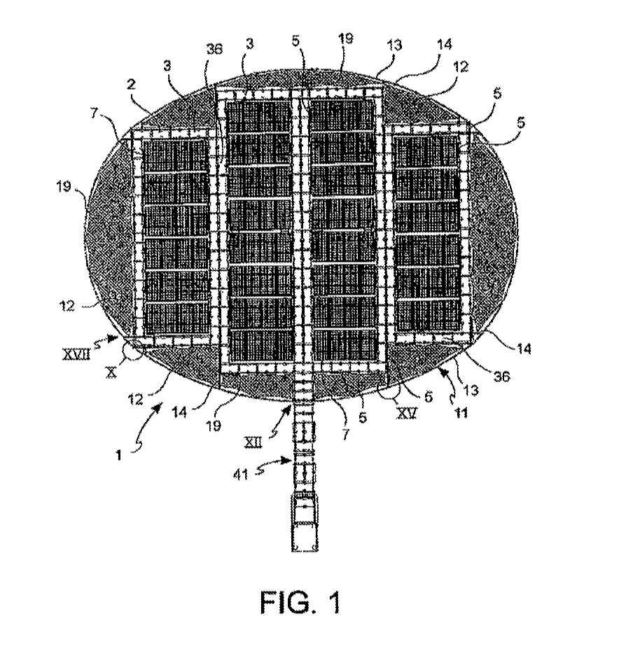

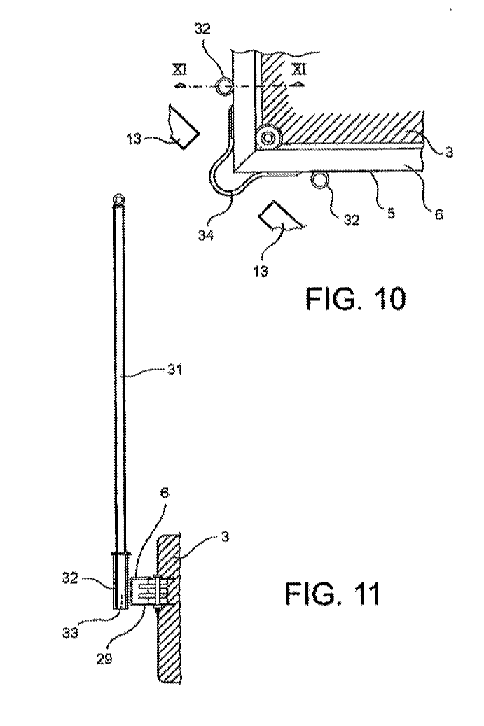

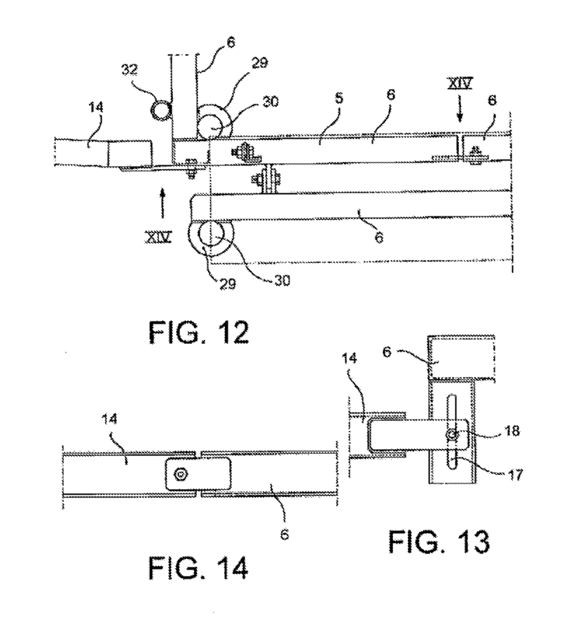

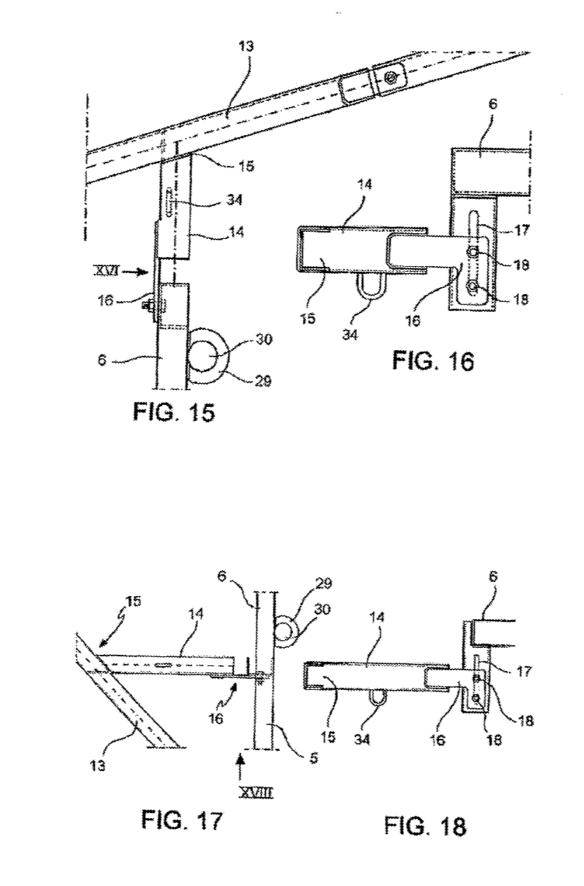

In accordance with a further aspect of the invention, the strengthening beams 6 may include straight beams capable of being joined to other straight lateral surfaces of the floating structure 2 and folded beams with an angle suitable for being coupled to lateral surfaces of the floating structure 2 which form angles and to protect these angles (see for instance FIG. 1, detail x, and FIGS. 10, 12).

FIGS. 10 and 11 illustrate a non limiting embodiment of a movable connection portion for the movable connection between an upright of a railing 31 and a strengthening beam 6. The portion of connection includes a tubular seat 32 for receiving a lower portion 33 of the upright of the railing 31.

FIGS. 10, 16 and 18 also portray portions 34 in the shape of an eyelet or eyebolt welded to the respective strengthening beams 6 or connecting beams 14 for connecting the net 19.

In accordance with a further embodiment of the invention, the supporting frame 9 for the photovoltaic panels 7 rests on two opposing strengthening beams 6 and the resting on at least one of the two opposing strengthening beams 6 is performed by putting an elastic spring 35 between the supporting frame 9 and the strengthening beam 6. In this way, the bearing structure of the photovoltaic panel 7 is rigid as regards the resting surface of the panel (support frame-panel interface) and elastically pliable within certain limits as regards the connection between the support frame 9 and the strengthening structure 5.

The structure thus devised may undergo slight deformations as a result of wave movement or local stress due to the walking of operators involved in inspections or maintenance interventions of system 1, without transmitting any deformation or stress to the photovoltaic panel 7.

Regarding this, it is also pointed out that the grating shape floating structure 3 has gangways 36 between the areas covered by photovoltaic panels 7.

Returning to the supporting structure 8 for the photovoltaic panels 7, in accordance with one embodiment, the supporting frame 9 comprises two long opposite sides and two short opposite sides and on each of the short opposite sides there are two annular seats 37 (preferably basically vertical cylindrical tubes) inserted vertically on the respective bolts or connecting column bolts 38 fixed to the strengthening beams 6 on which the supporting frame 9 is laid. A positioning plate 39 is connected to the free end of the connecting column bolt 38 so as to prevent the supporting frame 9 from coming off the connecting column bolt. Between a first annular seat on each short side and the corresponding strengthening beam there is a helical spring 35 positioned on the connecting column bolt 38 so that the helical spring 35 forms a spacer between the strengthening beam 6 and the supporting frame 9 and elastically prevents the supporting frame 9 from approaching the strengthening beam 6. Between a second annular seat of each short side and the positioning plate there is a second helical spring 40 inserted on the connecting column bolt 38 so that the supporting frame 9 rests rigidly against the strengthening beam 6 and the second helical spring 40 elastically prevents the supporting frame 9 from moving away from the strengthening beam 6.

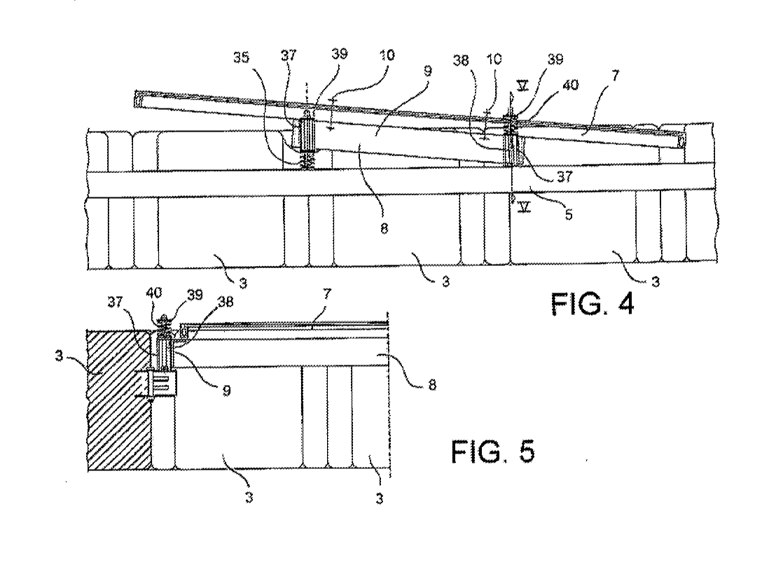

Thanks to this particular arrangement of the elastic springs 35, 40 we have a slight inclination of the supporting frame table 9 and of the photovoltaic panel 7 connected to it with respect to the table P of the floating structure 2 (FIGS. 4, 5).

In accordance with a further embodiment, the floating photovoltaic system 1 includes a landing stage 41 for connection with the shore.

An advantage of this is the fact that the landing stage 41 is formed in a modular manner from this floating structure 2 and from this strengthening structure 5 according to structural principles of the invention already described.

Particularly advantageously, the strengthening structure 5 makes preferably covered joints 42 which permit movement and rotation regarding two adjacent segments and particularly between two adjacent floating blocks 3, of the portion of floating structure forming the landing stage 41.

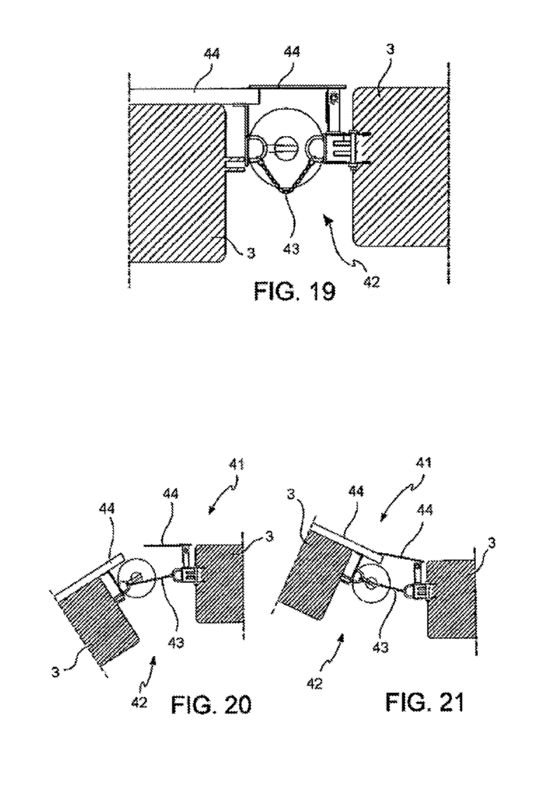

In accordance with one embodiment, the joint 42 may be made by a chain-like connection 43 with one or more portions of cover 44 (FIGS. 19, 20, 21).

The photovoltaic panels 7 are connected by cables to a control unit (not illustrated in the figures) containing inverters for transforming the direct current generated by the photovoltaic panels 7 into alternating current ready to be supplied to the national grid. The control unit can be supported by the floating structure of the system 1 or, alternatively, said control unit may be positioned on the shore. The electric cables may be extended along the floating structure and the landing stage and be connected to them or alternatively, the electric cables may be extended along the lake bottom to the control unit.

From the description provided until now, the expert of the sector may undoubtedly appreciate how the system 1 described in this invention achieves the above described purposes.

In particular, the system 1 adapts harmoniously to the landscape of the installation place, is easily adaptable to expansion needs, reduction of area and variations of shape and its structure follows the variations of the seasonal water levels, as well as the wave movement without affecting its correct operation.

Obviously, a specialised technician may make further modifications and variations to the photovoltaic system 1 described in this invention in order to satisfy contingent and specific needs. These modifications and variations are all contained within the protection of this invention as defined by the following claims.

1. Floating photovoltaic system including:
a floating structure with a series of floating modular blocks, said floating modular blocks being movably connected to form a basically flat floating grid with a float height;
a strengthening structure, parallel to the upper side of said floating structure and arranged within the float height, said strengthening structure having a series of strengthening beams, in which each one of said strengthening beams is movably connected to at least two floating modular blocks;
a supporting structure including one or more rigid supporting frames said rigid supporting frames being movably connected to said strengthening beams;
one or more photovoltaic panels fixed on said supporting frames;
characterized in that the floating photovoltaic system includes a holding and limiting structure to keep a carpet of aquatic plants, said holding and limiting structure being movably connected to said strengthening structure.

2. (canceled)

3. Floating photovoltaic system according to claim 1, in which said holding and limiting structure includes:
one or more limiting beams arranged at a distance from the floating structure so as to form a limiting line of the floating photovoltaic system;
a series of connection beams with an external end connected to the limiting beam and an internal end connected to the strengthening structure in a movable manner and adjustable in height so that the height of the limiting line can be adapted to floating line of the floating photovoltaic system;
a safety and holding net for the aquatic plants, said safety and holding net being placed in the space between the limiting line and the floating structure and said safety and holding net being connected to said limiting beams and to said strengthening beams.

4. Floating photovoltaic system according to claim 1, in which said floating blocks are formed of:
hollow bodies of a parallelepiped shape with a lower side, an upper side and four lateral sides which form four lateral corners;
a filling opening created in one of said lateral sides to regulate the upward thrust of the floating modular blocks;
connection interfaces arranged in the proximity of said lateral corners, said connection interfaces including flanges with through openings, said through openings being vertically superimposed and connected through the insertion of a connecting pin.

5. Floating photovoltaic system according to claim 4, in which floating modular blocks are made of synthetic material.

6. Floating photovoltaic system according to claim 4, in which said strengthening beams include open cross-section metal profiles with at least two connecting fins, said connecting fins protruding from said metal profile and delimited openings vertically superimposing the respective through openings of the connection interfaces of at least two floating modular blocks.

7. Floating photovoltaic system according to claim 1, in which said strengthening beams include one or more portions for connecting auxiliary structures chosen in the group including:
holding and limiting structures;
photovoltaic panel support structures;
railings;
landing stages; or
cableways.

8. Floating photovoltaic system according to claim 1, in which said supporting frame for the photovoltaic panels rests on two opposing strengthening beams through the interposition of spring between said supporting frame and said strengthening beam.

9. Floating photovoltaic system according to claim 8, in which said supporting frame includes two long opposing sides and two short opposing sides and two annular seats are formed at each of the opposing short sides, said annular seats being vertically inserted on the respective connection column bolts, said connection column bolts being fixed to the strengthening beams on which said supporting frame rests, and in which a positioning plate is connected to the free end of the connection column bolt so as to prevent the supporting frame from coming off the connection column bolt, in which:
between a first annular seat of each short side and the corresponding strengthening beam there is a helical spring positioned on the connection column bolt so that the helical spring forms a spacer between said strengthening beam and said supporting frame and so that the spring elastically prevents the supporting frame from approaching the strengthening beam; and
between said second annular seat of each short side and the positioning plate there is a second helical inserted on the connection column bolt so that the supporting frame rests rigidly against said strengthening beam and said second helical spring elastically prevents the supporting frame from moving away from the strengthening beams; and
in which said springs provides allow a slight inclination of the supporting frame and of the photovoltaic panels connected to it with respect to the upper side of the floating structure.

10. Floating photovoltaic system according to claim 1, including a floating landing stage to connect the floating photovoltaic system to the shore, in which said landing stage includes joints which permit a movement and rotation between two adjacent floating modular blocks.
